(19) United States
(12) Patent Application Publication
(10) Pub. No.: US 2010/0084166 A1
(43) Pub. Date: Apr. 8, 2010

(54) METHOD FOR FITTING AN ELECTRICAL COMPONENT TO A CONTACTING ELEMENT AND CONTACTING ELEMENT WITH AN ELECTRICAL COMPONENT

(76) Inventors: Norbert Knab, Appenweier (DE); Georg Schulze-Icking-Konert, Buehlertal (DE); Thomas Mohr, Buehlertal (DE); Stefan Kotthaus, Sinzheim (DE); Nikolas Haberl, Sinzheim (DE); Stefan Stampfer, Bietigheim-Bissingen (DE); Michael Mueller, Rutesheim (DE)

Correspondence Address: MERCHANT & GOULD PC, P.O. BOX 2903, MINNEAPOLIS, MN, 55402-0903, US

(21) Appl. No.: 12/532,981

(22) PCT Filed: Jan. 28, 2008
(86) PCT No.: PCT/EP08/50937

§ 371 Date: Sep. 24, 2009

(30) Foreign Application Priority Data
Mar. 26, 2007 (DE) 10 2007 014 337.2

(51) Int. Cl. H05K 7/20; H05K 1/16; H01R 43/00

(52) U.S. Cl. 174/252; 174/260; 29/840

(57) ABSTRACT

The invention relates to a method for equipping a contacting element (1), in particular a punched grid with an SMD component (4), comprising the following steps: proving the contact element (1) with a casing, a connector point (3) being provided in a recess (7) of the casing (5); placing the SMD component (4) on the connector point (3); and heating a thermally conductive element in order to heat the connector point (3) so that the SMD component (4) can be connected to the connector point (3).

The invention relates to a procedure for equipping contact elements with electric components as well as contacting elements with placed electric components.

Contacting elements, in particular punched grids or printed circuit board, usually serve for providing electric feed lines in a module. The punched grids comprise conductive structures with conductor paths, which are over-molded with a plastic material in order to ensure a dimensional stability. Depending on the field of application it can be necessary to provide the punched grid with electric elements, which therefore have to be connected with the conductor paths for example by soldering. Even though the partial soldering of wired components or printed circuit boards is possible at such punched grids, the soldering of SMD components (surface mounted device) onto the punched grid is not possible. The reason behind that is that for example the temperature stability of the plastics that are used for the over-molding of the punched grid is not sufficient to carry out the soldering of the SMD-component that usually takes place by an extensive heating (for example in a reflow oven) before the over-molding of the punched grid. A soldering of the SMD components before the over-molding of the punched grid with the plastic is also left out as possible alternative, because the temperature of the plastic, which is molded over the punched grid is usually higher than the melting temperature of the solder that is used for soldering the SMD-components on the punched grid. Furthermore mechanic deformations of the punched grid (contact elements) occurs during the molding process due to the high injection pressure and the high viscosity of the liquid plastic or possibly due to the high temperature of the liquid plastic, which can cause a damaging or destruction of already existing soldering connections between the punched grid and SMD components.

This task is solved by the procedure according to claim 1 as well as by the contacting element according to the subordinate claim.

Further advantageous configurations of the invention are provided in the dependent claims.

According to one aspect a procedure for equipping a contacting element, in particular a punched grid, with a SMD component is provided. The procedure comprises the steps of providing the contacting element with a casing, at which a connector point is provided in a recess of the casing; the placing of the SMD component on the connector point; and the local heating of a thermally conductive element, in order to heat the connector point, so that the SMD component is connected to the connector point.

The procedure provides the advantage that electric components are placed on a punched grid, even though it is already provided with a casing that is not heat-resistant. By the local heating of a thermally conductive element of the punched grid the heat can be brought directly to the connector point, so that the casing is not directly affected by the heat.

Furthermore a soldering material is provided before the heating between the connector point and the SMD component.

The local heating can be carried out by dipping the thermally conductive element into a solder bath, by induction, by resistance heating, by impinging with hot air, by heat thermal conduction with the aid of a placed stamp or by impinging with a laser.

Alternatively a protection plate can be set on the contacting element before the heating, so that the thermally conductive element reaches through an opening of the protection plate, and whereby the contacting element that is provided with the protection plate is introduced into a reflow oven.

Furthermore the connector point can be provided in the recess of the casing, whereby the heating of the thermally conductive element is only carried out maximally for a period of time until the contact bridge at the edge of the recess has reached a threshold temperature of the material of the casing.

According to a further aspect a contacting element, in particular a punched grid is provided for placing a SMD component. The contacting element comprises a conduction structure; a casing, which surrounds the conduction structure at least partially; a recess in the casing, so that a conducting area of a conduction structure that is not encased is not provided with a connector point; as well as a thermally conductive element, which is arranged at the conducting area, in order to deliver heat to the connector point.

Furthermore the thermally conductive element can be construed distant from the conductive area and be provided as integral part of the conductive area.

According to an embodiment the thermally conductive element is arranged at the conductive area, so that a better thermal conduction exists towards the connector point that to the position of the conductive area at the edge of the recess.

A heat dissipation can be provided at the conductive area and/or a heat dissipating structure of the conductive area between the point of the conductive area at the edge of the recess and the point, at which the thermally conductive element and the conductive area are in contact with each other.

### DRAWINGS

Preferred embodiments of the invention are subsequently further explained in the attached drawings. It is shown in:

FIG. 1 a top view on a punched grid, which is equipped with a SMD component;

FIG. 2 a procedural status during the placing of the SMD component onto the punched grid according to a first embodiment;

FIG. 3 a procedural status of the placing of the SMD component according to a further embodiment of the invention;

FIG. 4 a top view on a punched grid, which is equipped with a SMD component according to a further embodiment of the invention; and

FIG. 5 a punched grid, which is equipped with a SMD component and provided with a protection plate according to a further embodiment of the invention.

### Embodiments of the Invention

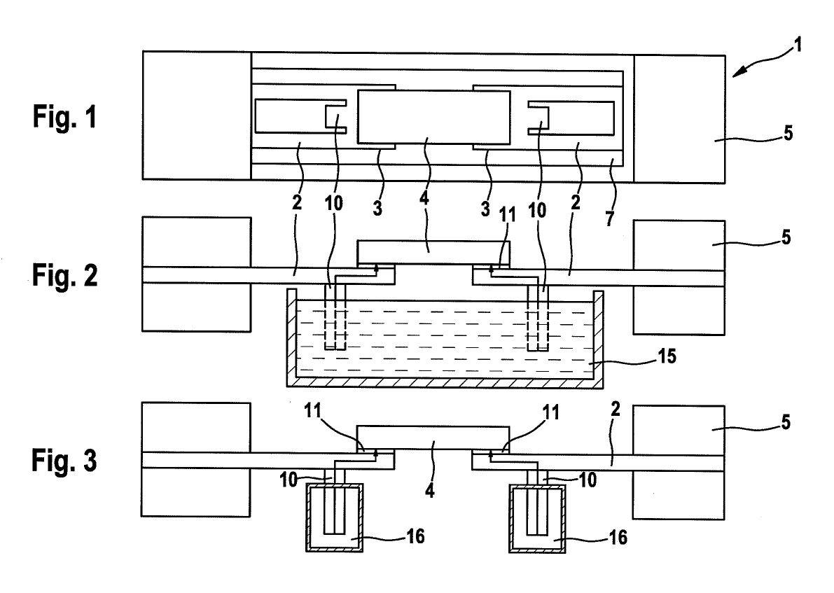

FIG. 1 shows an extract of a punched grid 1, which provided two contact bridges 2, which provided a connector point 3 at their ends. The connector points 3 serve for placing a SMD component and to contact there, so that it is electrically connected by the contact bridges 2.

The punched grid 1 is provided with a casing 5 made of plastic material, which is left blank in the area of the contact bridges and the SMD components 4, in order to enable the placing of the SMD component 4. The plastic material serves for protecting conducting paths of the punched grid 1 from unplanned contacts and provides furthermore a corrosion protection for the conductive paths. Instead of the plastic materials another material can also be used that are suitable for the encapsulation of the conductive paths of the punched grid 1 and that are not conductive. Usually the plastic material is placed on the punched grid 1 with the aid of an injection molding procedure, at which the plastic material is liquefied by a heat supply and is injected around the punched grid with the aid of a suitable mold.

The recesses in the punched grid for soldering the SMD component 4 on the contact bridges 2 are either introduced after the injection process into the punched grid 1 or the injection process takes place in such a way that the contact bridges 2 are not covered by the plastic material.

The SMD components 4 are usually soldered in a reflow process on printed circuit boards and such alike, in order to contact them. A reflow process means an extensive heating of the printed circuit board, in order to melt a solder paste, which is arranged between the connector points 3 and the contacts of the SMD components 4. But such a reflow process has the disadvantage that also the plastic material of the casing 5 melts or degrades thereby, and gets destroyed or deformed due to that. A reflow process for placing SMD components on a punched grid with a plastic casing is therefore not suitable.

Also the possibility to place the casing 5 after placing the SMD component 4 on the connector points 3 of the contact bridges 2, which means before the plastic material is injected around the conductive paths of the punched grid, is also omitted. The consequence of that is that due to the high temperature, which is required for liquidizing the plastic material the solder between the contacts of the SMD component 4 and the connector points 3 melts as well and during the injection process a detaching of the SMD component from the connector points, a destruction of the soldering points between the connector points 3 and the contacts of the SMD components 4 and such alike can occur.

According to the present invention it is therefore suggested to place the SMD component 4 at the contact bridges 2 after the molding of the conduction structure with the plastic material. As it can be seen in FIGS. 1 and 2 one part of the contact bridge 2 is therefore bent-off from a plane of the contact bridge 2. This is used as thermally conductive element 10 and therefore contacted with a heat source in order to conduct heat over the thermally conductive element 10 over the contact bridge 2 to the connector point 3. A soldering paste 11 is put on at the connector point 3, on which the SMD component 4 is placed.

As it can be seen in FIG. 1 the thermally conductive element 10 is preferably blanked out as a bridge from the inside of the contact bridge 2 and transversely, preferably vertically bent-off towards the plane of the contact bridges 2, so that the thermally conductive element 10 stands off vertically from the contact bridge 2. The thermally conductive element 10 is bent-off at a position of the contact bridge 2, which is closer to the connection area 3 than to the edge of the recess 7, in which no plastic material is located on the punched grid 1, and thus the contact bridges 2 are exposed.

Preferably the bridge of the thermally conductive element 10 is blanked into the contact bridge 2 in such a way that the thermally conductive element 10 is bent-off in the immediate proximity, in particular bordering at the connector point 3, to the contact bridge 2. The thermally conducting element 10 serves for delivering heat energy over the thermally conductive element 10 on the contact bridge 2 and to the connector point 3, so that the soldering paste 11 is melted there, in order to connect the SMD component 4 with the contact bridges 2. The heat is delivered over the contact bridge 2 also in the direction of the edge of the recess 7, which means to the plastic material of the casing 5 at the edge of the recess 7. Therefore the heat supply has to take place in such a way that the soldering paste 11 is melted, but the heat supply is taken away or switched-off as soon as the soldering process of the solder of the SMD component 4 onto the contact bridge 2 has finished, in order to prevent that the temperature of the contact bridge 2 reaches a threshold temperature of the plastic material at the edge of the recess 7, at which the plastic material melts or degrades.

As it is shown in FIG. 2 the heat supply can take place by dipping the thermally conductive elements 10 into a solder bath 15, in which melted solder is present at a temperature, which lies above the melting point of the solder. By dipping the thermally conductive elements 10 the temperature is delivered after a short period of time towards the connector points 3, so that the temperature increases there above the melting point of the solder of the solder paste 11, it liquidizes and therefore the SMD component solders at the connector points 3. Basically also the temperature of the contact bridges at the edge of the recess, at which the casing of the plastic material begins, begins to increase at the same time. The temperature of the solder material in the solder bath 15 is selected in such a way that the temperature at the connector point 3 exceeds the threshold temperature of the solder paste as soon as possible, in order to finish the soldering process, but the temperature at the edge of the recess reaches not the melting temperature of the plastic material until the soldering process is finished.

The embodiment of FIG. 3 shows a procedural state, at which the heat supply takes place by introducing heat into the thermally conductive elements 10 with the aid of an induction coil 16.

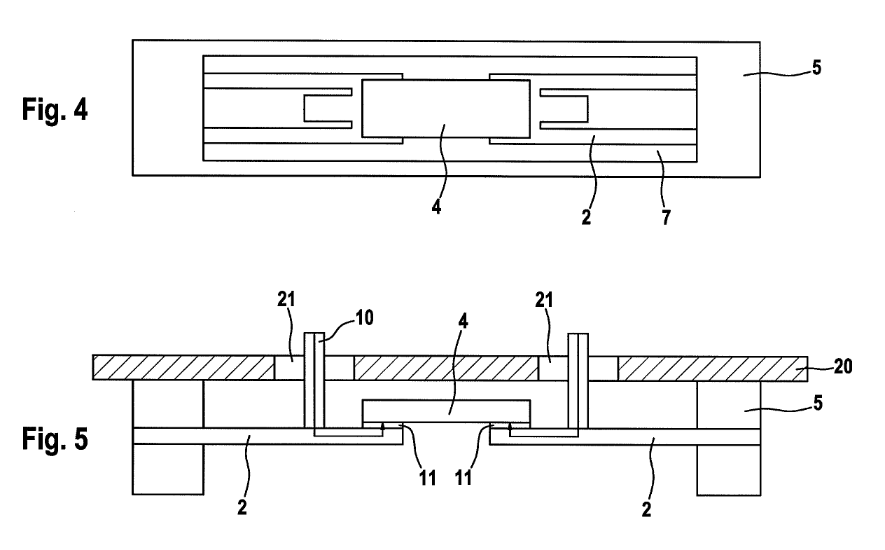

FIGS. 4 and 5 show a punched grid with a placed SMD component, at which the punched grid is provided with a protection plate 20, which provides openings 21, through which the thermally conductive elements 10 reach. Thereby the punched grid can also be introduced into a reflow oven, at which the heat of the heated air from the oven is delivered over the thermally conductive elements 10, which deliver the heat to the connector points 3. In the embodiments that are shown in FIGS. 4 and 5 the thermally conductive elements 10 are not bent-off towards one side of the contact bridges 2, which is opposed to the sides, on which the SMD component 4 is placed, as in the embodiments that are shown in FIGS. 1 and 3, but towards the same side as the SMD component 4.

Instead of a punched grid the invention can also be realized with a printed circuit board or another contacting element.

In order to prevent that the temperature increase at the edge of the recess at the contact bridges gets to high, heat dissipation devices can be provided along one or several contact bridges 2, which dissipate the heat from the corresponding contact bridge 2 into the environment. In particular the contact bridge 2 can be widened in the area between the edge of the recess 7 and the connection between the thermally conductive element lo and the connector point 3, in order to achieve thereby a larger surface for the dissipation of the heat. Such measures increase the period of time, during which a heat supply can be applied over the thermally conductive element 10, in order to solder the SMD component 4 but so that the temperature at the edge of the recess 7 does not achieve a melting temperature of the plastic material of the casing 5 or a temperature, at which a permanent deformation of the plastic materials can be caused.

Alternatively the thermally conductive elements 10 can also be heated with a laser or by a targeted impinging with hot air, in order to achieve the soldering of the SMD component at the connector point 3.

1-11. (canceled)

12. A method for equipping a punched grid with an SMD component, the method comprising:
providing a contacting element with a casing, wherein a connector point provided in a recess of the casing;
placing the SMD component on the connector point; and
locally heating a thermally conductive element to heat the connector point so that the SMD component can be connected to the connector point.

13. The method of claim 12, further comprising positioning a solder material between the connector point and the SMD component prior to heating.

14. The method of claim 12, further comprising heating by dipping the thermally conductive element in a soldering bath by one of induction, impinging with hot air, and impinging with a laser.

15. The method of claim 12, further comprising:
placing a protecting plate on the contacting element prior to heating so that the thermally conductive element reaches through an opening of the protecting plate; and
introducing the contacting element into a reflow-oven.

16. The method of claim 12, further comprising:
providing the connector point on a conducting area in the recess of the casing; and
heating the thermally conductive element for a period of time until the conducting area has reached a threshold temperature of the material of the casing (5) at the edges of the recess.

17. A contacting element, in particular a punched grid, for placing a SMD component, comprising:
a conductive structure;
a casing that at least partially surrounds the conductive structure;
a recess in the casing to provide an uncovered conducting area of the conductive structure with a connector point; and
a thermally conductive element arranged at the conducting area to supply heat to the connector point.

18. The contacting element of claim 17, wherein the thermally conductive element is arranged off-standing from the conducting area and provided as an integral part of the conducting area.

19. The contacting element of claim 17, wherein the thermally conductive element is arranged at the conducting area so that an heat conduction exists to the connector point that is better than to the position of the conductive area at the edge of the recess.

20. The contacting element of claim 17, further comprising at least one of a heat dissipation device at the conductive area and a heat dissipating structuring of the conductive area between the point of the conductive area at the edge of the recess and the point, at a contact between the thermally conductive element and the conductive area.

21. The contacting element of claim 17, further comprising a SMD component attached at the connector point.

22. The contacting element of claim 17, wherein the SMD component is a soldering element that melts at a certain ambient temperature and accumulates due to its surface tension at the connector point and thereby interrupts a current flow.
